(19) United States
(12) Patent Application Publication
(10) Pub. No.: US 2022/0216384 A1
(43) Pub. Date: Jul. 7, 2022

(54) ELECTRONIC DEVICE

(71) Applicant: CONTREL TECHNOLOGY CO., LTD., TAINAN CITY (TW)

(72) Inventors: Jen-Hung LO, TAINAN CITY (TW); YU-CHENG YANG, TAINAN CITY (TW); CHIH-HAO TSAI, TAINAN CITY (TW); TSAN-JEN CHEN, TAINAN CITY (TW)

(21) Appl. No.: 17/568,978

(22) Filed: Jan. 5, 2022

(30) Foreign Application Priority Data
Jan. 7, 2021 (TW) 110100639

(51) Int. Cl. H01L 33/62; H05K 3/32; B23K 1/005; H01L 23/00; H01L 27/15; B23K 1/00

(52) U.S. Cl. CPC H01L 33/62; H05K 3/32; B23K 1/0056; H01L 24/83; H01L 2933/0066; B23K 1/0016; H01L 2224/81815; H01L 2924/12041; H01L 27/153

(57) ABSTRACT

An electronic device includes a plurality of micro-optoelectronic components and a circuit board. Each of micro-optoelectronic components includes a semiconductor layer, and metal electrodes electrically coupled to the semiconductor layer and exposed on a surface of the semiconductor layer. The circuit board includes a metal circuit layer and a plurality of solder joints. The solder joints are formed on said metal circuit layer, and connected to said metal electrodes. A portion of each of metal electrodes and each of solder joints are welded to form a metal crystalline structure. The metal crystalline structure includes the composition of the metal electrode and/or the composition of the metal circuit layer.

### BACKGROUND OF THE INVENTION

### 1. Field of the Invention

The present invention relates to electronic circuits, and in particular refers to an electronic device with semiconductor components.

### 2. Description of the Related Art

The metal electrode of the semiconductor element and the conductive circuit of the circuit board are connected through the medium (solder), and through the reflow technology, the semiconductor component is permanently fixed on the conductive circuit. In this way, the heating time is long, and it is impossible to select a specific welding position.

Furthermore, with the development of semiconductor technology, the side length of semiconductor components is getting smaller and smaller, and the relative metal electrode size is getting smaller and smaller. If you need to form solder on the conductive circuit or the metal electrode of the semiconductor component through the reflow technology, and then heat the solder for soldering, it can be seen that the difficulty of joining is higher.

### SUMMARY OF THE INVENTION

In view of the above-mentioned deficiencies, the welding of the electronic device of the present invention does not use solder, and the heating is only directed to the part (solder joints) of the conductive circuit layer to join the metal electrodes of the semiconductor components.

In order to achieve the above object, the electronic device of the present invention comprises a plurality of micro-optoelectronic components and a circuit board. Each of micro-optoelectronic components comprises a semiconductor layer and metal electrodes. The metal electrodes are electrically coupled to the semiconductor layer and exposed on the surface of the semiconductor layer. The circuit board comprises a metal circuit layer and a plurality of solder joints. The solder joints are formed on the metal circuit layer, and connected to the metal electrodes of the micro-optoelectronic components. A portion of each of metal electrodes and each of solder joints of the metal circuit layer are welded to form a metal crystalline structure. The metal crystalline structure comprises the composition of the metal electrode and/or the composition of the metal circuit layer.

In order to achieve the above object, the electronic device of the present invention comprises a semiconductor component and a circuit board. The semiconductor component comprises a semiconductor layer and a metal electrode. The metal electrode is electrically coupled to the semiconductor layer and exposed on a surface of the semiconductor layer. The circuit board comprises a metal circuit layer and a solder joint. A portion of the metal electrode and the solder joint are welded to form a metal crystalline structure. The metal crystalline structure comprises a composition of the metal electrode and/or composition of the metal circuit layer.

In this way, the metal crystalline structure formed by welding can stably electrically connect the circuit board metal circuit and the semiconductor component, and can optimize the existing semiconductor welding process to improve production efficiency.

The detailed composition, steps, structure, characteristics, operation or use of the electronic device provided by the present invention will be described in the detailed description of the subsequent preferred embodiments. However, those with ordinary knowledge in the field of the present invention should be able to understand that these detailed descriptions and specific embodiments listed in the implementation of the present invention are only used to illustrate the present invention, and are not intended to limit the scope of the patent application of the present invention.

### BRIEF DESCRIPTION OF THE DRAWINGS

FIG. 1 is a schematic diagram of the electronic device of the present invention.

FIG. 2 is a partial enlarged view of the electronic device of FIG. 1.

FIG. 3 is a cross-sectional view along the line 3-3 in FIG. 2.

FIG. 4 is a cross-sectional view along the line 4-4 in FIG. 2.

FIG. 5 is an image of the metal electrodes of the semiconductor components of the electronic device and the metal circuit layer of the circuit board formed by welding, and taken through an electron microscope.

FIG. 6 is a schematic diagram of the laser beam projected to the metal circuit layer of the circuit board.

### DETAILED DESCRIPTION OF THE INVENTION

Hereinafter, the corresponding preferred embodiments are listed in conjunction with the drawings to illustrate the components, connections, and effects of the electronic device of the present invention. However, the composition, elements, quantity, components, size, appearance and steps of the electronic device in each of the drawings are only used to illustrate the technical features of the present invention, and not to limit the present invention.

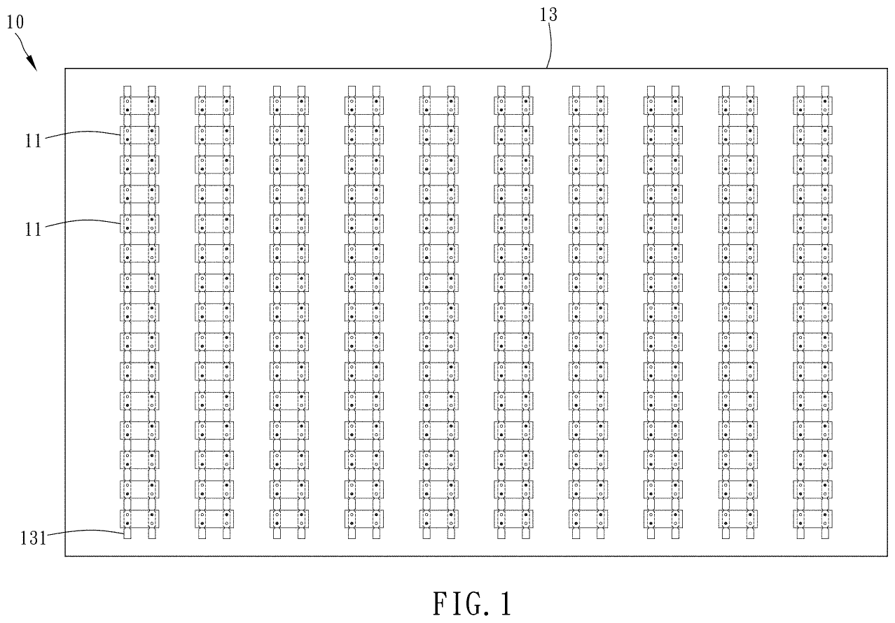

As shown in FIG. 1, the electronic device 10 of the present invention comprises a plurality of semiconductor components 11 and a circuit board 13. The semiconductor components 11 are also called dies. The circuit board 13 comprises a metal circuit layer 131. The metal circuit layer 131 is exposed on the top surface of the circuit board 13, and the exposure can be part or all of the metal circuit layer. The metal circuit layer 131 is used to transmit the power and signals required by the semiconductor components 11. The metal circuit layer includes metal materials or alloys such as gold, silver, copper, aluminum, nickel, and stainless steel.

In this embodiment, semiconductor components 11 take micro-optoelectronic components as an example. The micro-optoelectronic components include one side whose length is between 1-1000 microns. In other embodiments, the semiconductor components can also be dies or combinations of other functions, such as processors, drive components, passive components, and active components.

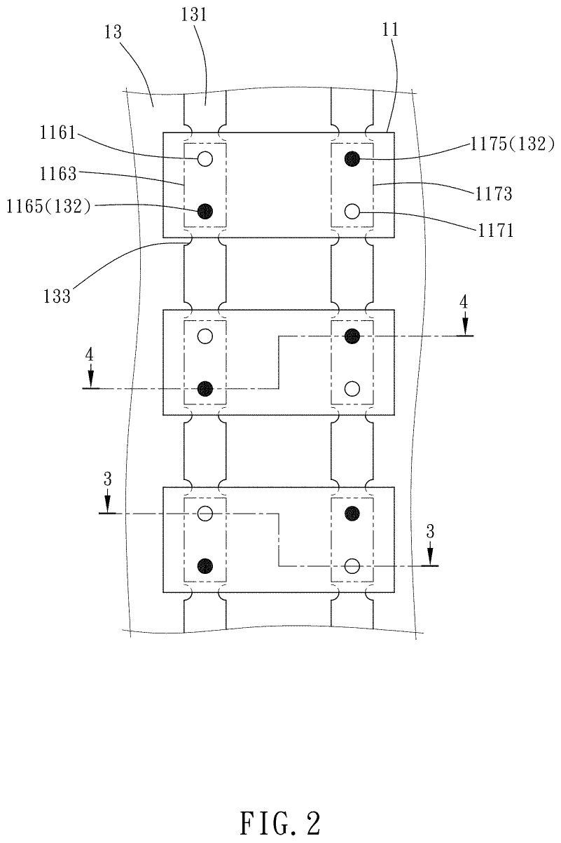

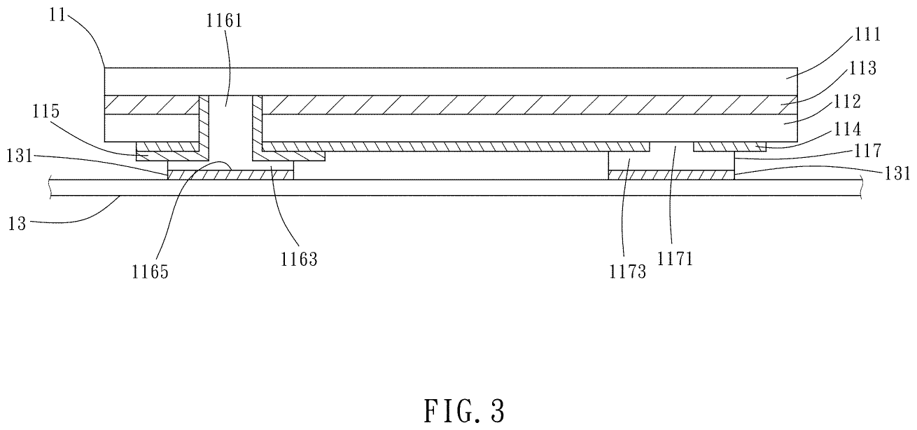

As shown in FIGS. 2-4, the semiconductor components 11 are welded and fixed on the metal circuit layer 131 of the circuit board 13, so that the two form an electrical connection. The circuit board 13 comprises a plurality of solder joints 132. The solder joints 132 are formed on the metal circuit layer 131, and connected to the metal electrodes of the semiconductor components 11.

In this embodiment, the semiconductor components 11 comprise an N-type semiconductor layer 111, a P-type semiconductor layer 112, a light-emitting layer 113, a conductive layer 114, an insulating layer 115, an N-metal electrode 116, and a P-metal electrode 117. The structure from top to bottom is N-type semiconductor layer 111, light-emitting layer 113 and P-type semiconductor layer 112. The materials of the N-metal electrode 116 and the P-metal electrode 117 are, for example, metal materials or alloys such as gold, copper, silver, and aluminum.

The N-metal electrode 116 comprises a vertical structure 1161 and a horizontal structure 1163 extending from the vertical structure 1161 (the double-dot chain line in FIG. 2 represents the range). The vertical structure 1163 passes through the P-type semiconductor layer 112 and the light-emitting layer 113, and is electrically connected to the N-type semiconductor layer 111. The horizontal structure 1163 is exposed at the bottom of the semiconductor component 11. The conductive layer 114 connects to the P-type semiconductor layer 112. The insulating layer 115 is located between the N-metal electrode 116, the P-type semiconductor layer 112, the light-emitting layer 113, and the conductive layer 114 to avoid the N-metal electrode 116 and the P-metal electrode 117 short. The P-metal electrode 117 comprises a vertical structure 1171 and a horizontal structure 1173 extending from the vertical structure 1171 (the double-dot chain line in FIG. 2 indicates the range). The vertical structure 1171 of the P-metal electrode 117 passes through the conductive layer 114 to connect to the P-type semiconductor layer 112. The horizontal structure 1173 of the P-metal electrode 117 is exposed at the bottom of the semiconductor component 11. The vertical structures 1161 and 1171 can be formed by via technology.

The N-type semiconductor layer 116 and the P-type semiconductor layer 117 provide electrons and holes respectively. The light-emitting layer 113 is used to convert electricity into light, and the material of the light-emitting layer 113 can change the color of light.

In other embodiments, the structure (layer) combination of other functional semiconductor components 11 and the number of metal electrodes will be different. Therefore, the number of semiconductor layers and metal electrodes can be at least one each, and more can be three or more. In addition, the structure of the N-metal electrode 161 and the P-metal electrode 171 can also be different.

The metal circuit layer 131 of the circuit board 13 comprises a plurality of marks 133, and the N-metal electrodes 161 and the P-metal electrodes 171 of the semiconductor components 11 are located between the marks 133. The marks 133 are used to assist the positioning of the semiconductor components. The marks 133 of this embodiment are semicircular gaps, and the shape of the gaps in other embodiments may be other geometric shapes or adopt other forms, such as patterns, colors, or words.

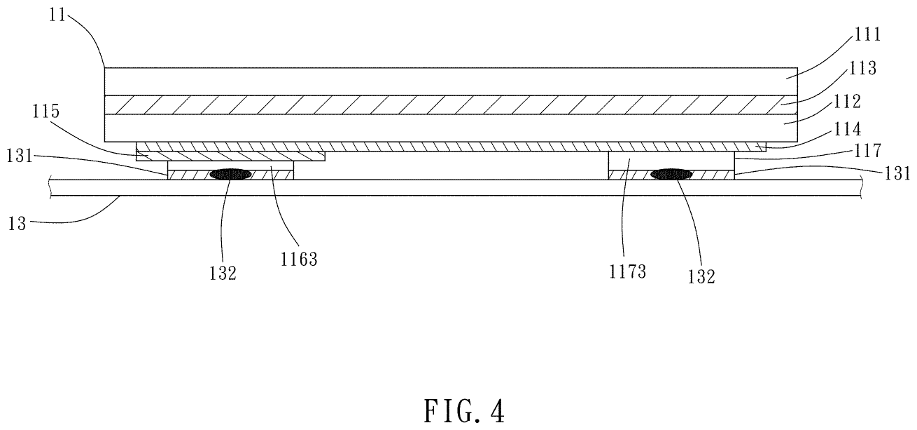

The welding is to heat the solder joints 132 to form a plurality of molten pools between the solder joints 132 and a portion of each of the metal electrodes 161 and 171 of the semiconductor components 11, as shown in the elliptical area of FIG. 4, and after cooling, multiple metal crystalline structures are formed.

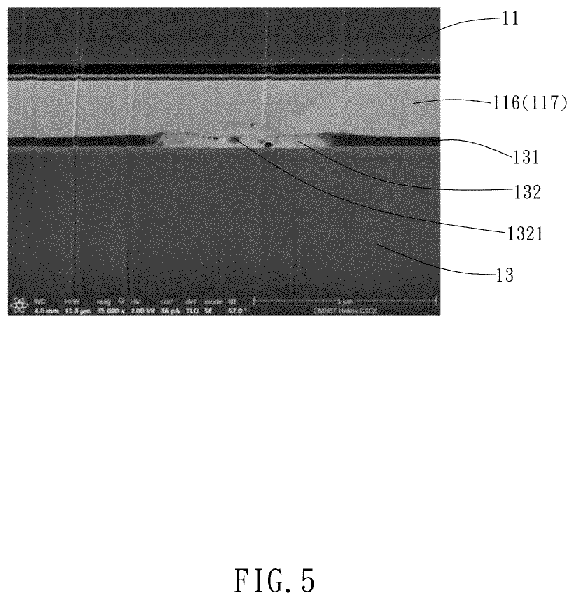

The molten pools are to heat the metal circuit layer 131 or the metal electrodes 161, 171 to its melting point, so that the heated part changes from solid to liquid or paste, and the liquid or paste is cooled to form metal crystalline structures and the metal circuit layer 131 or the metal electrodes 161, 171 are connected together, as shown in FIG. 5.

In this embodiment, the heating is through the laser beam, so that the laser beam interacts with the metal material of the solder joints 132 to melt. The solder joints 132 are part of the metal circuit layer 131 and are the same material as the metal circuit layer 131.

The heating temperature is related to the material or composition of the metal circuit layer 131 and the metal electrode 116, 117. For example, conductive metals such as nickel, gold, and copper above 1000 degrees Celsius, and conductive metals such as silver and aluminum at 500 degrees to 1000 degrees Celsius. Therefore, the heating temperature of the present invention is usually greater than 430 degrees Celsius. The range and size of the solder joints 132 are related to the focusing range of the laser beam.

In this embodiment, the hollow circles represent the positions of the vertical structures 1161 and 1171, and the solid circles represent the welding positions, that is, the overlapped and connected positions of the portions 1165 of the N-metal electrodes 116, the portions 1175 of the P-metal electrodes 117, and the solder joints 132.

Since the position structures that the horizontal structures 1163 and 1173 are directly opposite or connected to the respective vertical structures 1161 and 1171 are not suitable for welding. Therefore, the welding positions are selected to deviate from the vertical structures 1161 and 1171. The deviation refers to the vertical projection of the vertical structures 1161 and 1171 outside the range of the horizontal structures 1163 and 1173.

Take the uppermost semiconductor component 11 in FIG. 2 as an example of the deviation method. The horizontal structure 1163 of the N-metal electrode 116 is rectangular, and the vertical structure 1161 is located at the top in FIG. 2. Therefore, the welding position (i.e., the portion 1165 of the N-metal electrode 116) can be selected at the position below the vertical structure. Similarly, since the horizontal structure 1173 of the P-metal electrode 117 is rectangular, and the vertical structure 1171 is at the bottom of FIG. 2, the welding position (that is, the portion 1175 of the P-metal electrode 117) can be selected as the position above the vertical structure.

In other embodiments, since the range of the horizontal structures is larger than the vertical structures, the horizontal structures may be other shapes, such as a circle or an ellipse, the welding positions can still choose to deviate from the vertical structures.

As shown in FIG. 5, the figure is an image of the welding of portions of the metal electrodes of the semiconductor components and the solder joints, and taken through an electron microscope. The metal crystalline structure includes bubble or air holes 1321, which are holes left by the molten pool gas during the bonding process of the solder joints 132 and the metal electrodes 116 and 117 of the semiconductor component 11. In addition, the solder joints 132 and the portions 1165 and 1175 of the metal electrodes 116 and 117 are not damaged by laser processing to ensure the structural stability of the semiconductor component 11. In other embodiments, air holes may not exist.

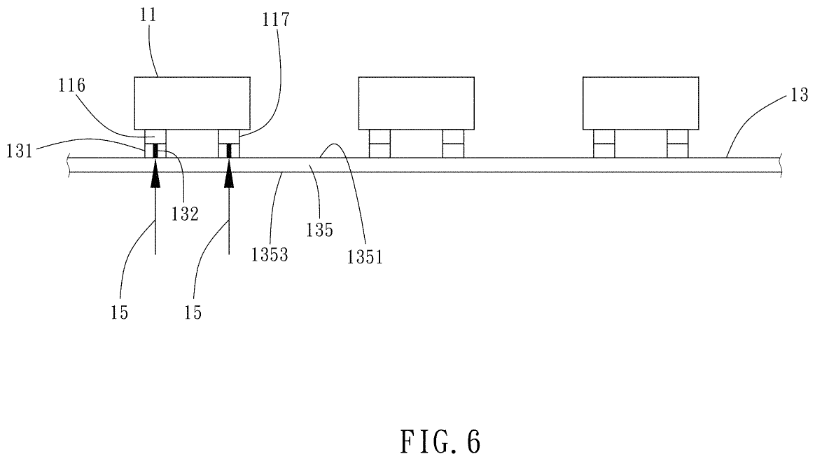

As shown in FIG. 6, the circuit board 13 comprises a transparent substrate 135, and the metal circuit layer 131 is formed on the top surface 1351 of the transparent substrate 135. The heating of the welding involves projecting the laser beam 15 from the bottom surface of the transparent substrate 135 and focusing on the solder joints 132, so that the solder joints 132 are melted with the laser beam 15 in a short time to form a molten pool (the black column area in the drawing). The top surface of the solder joint 132 is in contact with the portion of the metal electrode of the semiconductor component 11, and then after the laser beam 15 stops projecting, the liquid or paste metal components in the molten pool range are cooled to achieve efficient welding in a short time. It can be seen that the melting point temperature of the metal circuit layer 131 can be lower than or the same as the melting point temperature of the metal electrode.

The molten pools penetrate the top surface and bottom surface of the metal circuit layer 131, and located at the solder joints 132, and comprise portions of the metal electrodes. The top surface of metal circuit layer 131 is contacted with the metal electrode 116, 117. Therefore, the composition of the molten pools comprises the composition of the metal circuit layer 131 and the metal electrodes. However, in other embodiments, the molten pools may not penetrate the metal circuit layer 131, but is formed between the top surface of the metal circuit layer 131 and the metal electrodes. In addition, molten pools can also be formed on the edges of the metal circuit layer 131 and the metal electrodes that are in contact to form metal crystalline structures.

Since metal can efficiently transfer heat, in other embodiments, although the laser beam heats the solder joints 132, the heat is transferred to the portions 1165 of the N-metal electrodes 116 and the portions 1175 of the P-metal electrodes 117 that are in contact with the solder joints 132. Therefore, when the melting point of the composition of the N-metal electrodes 116 and the P-metal electrodes 117 is lower than the melting point of the composition of the metal circuit layer 131, during the heating process, the portions 1165 of the N-metal electrodes 116 and the portions 1175 of the P-metal electrodes 117 that contact the metal circuit layer 131 first reach the melting point of the material through heat transfer, the portions 1165 of the N-metal electrodes 116 and the portions 1175 of the P-metal electrodes 117 form molten pools, and are welded to the solder joints 132 after cooling.

Through the laser welding operation, the local metal can be heated to the melting point of the metal faster than the reflow technology, so as to effectively weld the two metal materials (the solder joints of the metal circuit layer and the metal electrodes of the semiconductor component) together to avoid heat accumulation and damage the structure of the semiconductor components.

In other embodiments, the laser beam can also be projected from the side of the top surface of the circuit board to the metal circuit layer. Therefore, the circuit board is not limited to comprising the transparent substrate.

In this way, the electronic device of the present invention can gradually complete the fusion of multiple semiconductor components with metal electrodes on the metal circuit layer through the projection of a laser beam, so as to improve the process efficiency of a large number of semiconductor components.

Because the electronic device of the present invention can effectively combine semiconductor components and circuit boards, and does not require the use of solder or media, the process of soldering and reflow operations can be omitted to improve efficiency.

Furthermore, the welding of the present invention can selectively heat the solder joints of the metal circuit layer without heating the whole or the metal electrodes of the semiconductor components. Therefore, the structure or function of the semiconductor components is less likely to be damaged by heat accumulation.

Finally, it is emphasized again that the constituent elements disclosed in the previously disclosed embodiments of the present invention are only examples and are not used to limit the scope of the present invention. The substitution or change of other equivalent elements should also be covered by the scope of the patent application of the present invention.

What is claimed is:

1. An electronic device, comprising:
a plurality of micro-optoelectronic components, each of said micro-optoelectronic components comprising a semiconductor layer and a metal electrode, said metal electrode being electrically coupled to said semiconductor layer and exposed on a surface of said semiconductor layer; and
a circuit board comprising a metal circuit layer and a plurality of solder joints, said solder joints being formed on said metal circuit layer, and connected to said metal electrodes of said micro-optoelectronic components, a portion of each of said metal electrodes and each of said solder joints being welded to form a metal crystal structure, said metal crystalline structure comprising at least one of a composition of said metal electrode and a composition of said metal circuit layer.

2. The electronic device as claimed in claim 1, wherein each of said solder joints and said portion of each of said metal electrodes are welded by heating each of said solder joints to form a molten pool between each of said solder joints and said portion of each of said metal electrodes so that said metal crystalline structure is formed after cooling.

3. The electronic device as claimed in claim 2, wherein the heating each of said solder joints is performed by a laser beam.

4. The electronic device as claimed in claim 2, wherein said molten pool is formed at said portion of each of said metal electrodes.

5. The electronic device as claimed in claim 2, wherein said molten pool is formed on said metal circuit layer and located at each of said solder joints, and a top surface of said metal circuit layer is in contact with said portion of each of said metal electrodes.

6. The electronic device as claimed in claim 1, wherein each of said metal electrodes comprises a vertical structure and a horizontal structure, said vertical structure being coupled to said semiconductor layer and said horizontal structure, said horizontal structure being exposed on said surface of said semiconductor layer; said multiple metal crystalline structures are connected to said horizontal structures of said metal electrodes of said micro-optoelectronic components.

7. The electronic device as claimed in claim 6, wherein said horizontal structures deviate from said vertical structures.

8. The electronic device as claimed in claim 1, wherein said circuit board further comprises a transparent substrate, and said metal circuit layer is formed on said transparent substrate.

9. An electronic device, comprising:
a semiconductor component comprising a semiconductor layer and a metal electrode, said metal electrode being electrically coupled to said semiconductor layer and exposed on a surface of said semiconductor layer; and
a circuit board comprising a metal circuit layer and a solder joint, said solder being formed on said metal circuit layer, and connected to said metal electrode, a portion of said metal electrode and said solder joint being welded to form a metal crystalline structure, said metal crystalline structure comprising at least one of a composition of said metal electrode and a composition of said metal circuit layer.
